(19) United States
(12) Patent Application Publication
(10) Pub. No.: US 2025/0108659 A1
(43) Pub. Date: Apr. 3, 2025

(54) AUTOMATIC IMAGE PAINTING DEVICE AND METHOD FOR DRAWING CHARACTERS TO BE PAINTED BY THE DEVICE

(71) Applicants: Jung Kyu PARK, Daegu (KR); RP INC., Daegu (KR)

(72) Inventors: Jung Kyu PARK, Daegu (KR); Sung Gun LEE, Daegu (KR); Kwang Ho WOO, Daegu (KR); Jeong Beak KIM, Daegu (KR)

(73) Assignees: Jung Kyu PARK, Daegu (KR); RP INC., Daegu (KR)

(21) Appl. No.: 18/717,896

(22) PCT Filed: Oct. 12, 2022
(86) PCT No.: PCT/KR2022/015351

§ 371 Date: Dec. 14, 2024

(30) Foreign Application Priority Data
Dec. 9, 2021 (KR) 10-2021-0175357
May 13, 2022 (KR) 10-2022-0058761
May 31, 2022 (KR) 10-2022-0066443

(51) Int. Cl. B44D 2/00; B05B 12/00

(52) U.S. Cl. CPC B44D 2/00; B05B 12/004

(57) ABSTRACT

The automatic image painting device according to the present invention is a device for painting a specific image by spraying paint on a target surface, comprising a paint spray nozzle unit for spraying paint on the target surface in a straight-line pattern of a predetermined length, a support frame unit that supports the paint spray nozzle unit to enable movement along the X-axis, Y-axis, and Z-axis, a direction changing unit that rotates the paint spray nozzle unit at a predetermined position on the support frame unit to change the orientation of the straight-line pattern, and a control unit for controlling the movement of the paint spray nozzle unit on the support frame unit and the rotational movement of the paint spray nozzle unit.

### TECHNICAL FIELD

This invention relates to an automatic image painting device and a method for drawing characters to be painted by the device. More specifically, the invention pertains to an automatic image painting apparatus capable of automatically painting images of various widths, and a character drawing method that allows users to easily draw characters to be painted by the automatic painting apparatus.

### BACKGROUND ART

When painting an image of a specific object on the wall, traditionally the workbench is suspended from a rope using a gondola from the rooftop, allowing the work platform to move up and down. Workers would then stand on this platform and perform the painting work directly.

Additionally, in the case of target surfaces such as floors, workers paint manually by looking at the image design.

The aforementioned methods pose problems due to the manual nature of painting, such as increased time and labor costs, as well as variations in quality depending on the skill level of the workers.

Efforts have been made to address these issues by developing automatic painting devices. However, conventional automatic painting devices have a problem with their low accuracy when painting specific images.

In particular, in the case of images corresponding to perspective, the width of the image may vary, and it is difficult to respond flexibly to such situation. Maintaining a consistent coating thickness along with these width variations is a significant challenge that needs to be addressed in the painting industry.

Therefore, there is an urgent need for research aimed at improving the accuracy of images and maintaining a consistent thickness of the paint layer to enhance the quality of image painting.

Meanwhile, in order for the automatic painting device to paint characters, character data for painting is required.

For example, character data may include all the necessary information to define characters, such as the type, size, stroke thickness/length, and so on.

Workers must first generate character data and then input the character data into the automatic painting device, and the environment for easily generating such character data (for drawing characters) is insufficient.

Meanwhile, Republic of Korea Registered Patent No. 10-1720897 B1 (issued on Mar. 22, 2017) introduces a method for font generation using spacing integration between characters and a computer program executing this method. However, this method merely focuses on adjusting the visual area between characters uniformly, failing to provide a solution for facilitating the easy drawing of various characters by operators.

### DETAILED DESCRIPTION OF THE INVENTION

### Technical Problem

The purpose of this invention is to provide an automated image painting device that may flexibly adapt to changes in the state of the painting process for areas with varying widths, while simultaneously maintaining a consistent thickness of the coating layer, thereby preventing deterioration in the quality of painting.

The purpose of this invention is to provide a method for easily drawing characters to be painted by an automated painting device.

### Technical Solution

According to one embodiment of the present invention, an automatic image painting device for painting a specific image on a target surface by spraying paint, comprising: a paint spray nozzle unit for spraying paint on the target surface in a straight-line pattern of a predetermined length; a support frame unit that supports the paint spray nozzle unit to enable movement along the X-axis, Y-axis, and Z-axis; a direction changing unit that rotates the paint spray nozzle unit at a predetermined position on the support frame unit to change the orientation of the straight-line pattern; and a control unit for controlling the movement of the paint spray nozzle unit on the support frame unit and the rotational movement of the paint spray nozzle unit, wherein the control unit controls the Z-axis movement of the paint spray nozzle unit on the support frame unit to adjust the distance between the paint spray nozzle unit and the target surface, thereby regulating the width of the specific image painted on the target surface, and controls the movement speed of the paint spray nozzle unit along the X-axis and Y-axis on the support frame unit to adjust the coating thickness of the specific image painted on the target surface.

According to one embodiment of the present invention, the control unit can, when the width of the first line portion included in the specific image is narrower than the second line portion, change the state of the paint spray nozzle unit to paint the second line portion. This is accomplished by moving the paint spray nozzle unit along the Z-axis to increase the distance between the paint spray nozzle unit and the target surface and reducing the speed of the movement, based on the position of the paint spray nozzle unit, in order to paint the second line portion.

According to one embodiment of the present invention, the specific image includes a right downward curved line portion or a left downward curved line portion. The control unit, to ensure that the right downward curved line portion or the left downward curved line portion is painted, controls the direction changing unit to gradually increase the rotation angle of the paint spray nozzle unit and moves the paint spray nozzle unit along the pitch axis and Y-axis on the support frame unit at variable speeds. Additionally, the control unit moves the paint spray nozzle unit along the Z-axis to vary the distance between the paint spray nozzle unit and the target surface.

According to one embodiment of the present invention, the control unit may control the paint spray nozzle unit and the direction changing unit so that the curvature radius of the outer line of the right downward curved line portion or the left downward curved line portion painted by the paint spray nozzle unit may vary.

According to one embodiment of the present invention, a method of drawing characters for drawing characters to be painted by an automatic painting device, comprising: displaying a character drawing user interface to the user on the display; receiving character drawing input information from the user via the input unit; and displaying character drawing result information corresponding to the character drawing input information to the user on the display; wherein the displaying the character drawing user interface includes: displaying a plurality of input icons arranged in horizontal and vertical directions to allow the user to input strokes of the character, and further displaying vertical direction movement icons to move the plurality of input icons in the vertical direction and horizontal direction movement icons to move the plurality of input icons in the horizontal direction.

According to one embodiment of the present invention, the step of displaying the character drawing user interface display block icons consisting of multiple blocks, each block representing multiple input icons grouped together. The step of displaying the character drawing result information involves displaying the input icons selected by the user among the multiple input icons. This may be achieved by distinguishing the blocks corresponding to the selected input icons from the unused blocks within the multiple blocks of the block icon, making them visually distinct to the user.

According to one embodiment of the present invention, the step of displaying the character drawing result information involves displaying the position of the start and end points of the strokes of the characters entered by the user. This may be achieved by displaying distance icons containing information about the distance of the start and end points of the strokes from a certain reference point in both horizontal and vertical directions.

According to one embodiment of the present invention, the character drawing method further includes a step of storing motion mechanism information of the paint spray nozzle unit of the automated painting device in memory. The step of displaying the character drawing user interface may include displaying a motion interface capable of simulating the motion of the paint spray nozzle unit.

According to one embodiment of the present invention, the step of displaying the character drawing result information may include displaying motion icons representing the motion of the paint spray nozzle unit on the characters entered by the user.

According to one embodiment of the present invention, the step of displaying the character drawing result information may include displaying the painting image that the paint spray nozzle unit paints on the characters entered by the user.

According to one embodiment of the present invention, the motion interface may include speed control icons that allow adjustment of the movement speed of the motion icons.

According to one embodiment of the present invention, the motion interface may include thickness adjustment icons that allow adjustment of the thickness of the painting image.

### Effects of the Invention

According to the present invention, the automated image painting device may flexibly adapt to changes in the state of the painting process for areas with varying widths when painting a specific image.

Additionally, despite variations in the image's width, the coating thickness may be maintained consistently, preventing any decline in painting quality.

Furthermore, manual intervention is not required during the process of painting a specific image, minimizing the time and cost of the painting process.

According to the character drawing method of the present invention, the automated painting device may easily draw the characters to be painted, facilitating the task for the operator.

### BRIEF DESCRIPTION OF THE DRAWINGS

FIG. 1 is a schematic block diagram of the configuration of a character drawing system implementing the character drawing method according to one embodiment of the present invention.

FIG. 2 is a schematic flowchart diagram of the character drawing method according to one embodiment of the present invention.

FIG. 3 is a schematic diagram of the character drawing user interface provided by the character drawing method according to one embodiment of the present invention.

FIG. 4 is a schematic diagram for explaining the vertical direction movement icon and the horizontal direction movement icon provided by the character drawing method according to an embodiment of the present invention.

FIG. 5 is a schematic diagram for explaining the character editing interface provided by the character drawing method according to an embodiment of the present invention.

FIG. 6 is a schematic diagram for explaining the motion icon provided by the character drawing method according to an embodiment of the present invention.

FIG. 7 is a block diagram for explaining the automatic image painting device according to the present invention.

FIG. 8 is a diagram illustrating the process of a specific image being painted on a target surface by the automatic image painting device according to the present invention.

FIGS. 9 and 10 are diagrams illustrating the distance from the target surface and the unit distance traveled per unit time (speed) for the coating spray nozzle unit used to paint a specific area.

FIG. 11 is a perspective view illustrating the automatic image painting device according to another embodiment of the present invention.

FIG. 12 is a side view illustrating the state in which the automatic image painting device depicted in FIG. 11 is being towed by a towing vehicle.

FIG. 13 is a perspective view illustrating the automatic image painting device depicted in FIG. 12.

FIG. 14 is a side view illustrating the state of adjusting the height of the trailer with the first height adjustment unit depicted in FIG. 12.

FIG. 15 is a side view illustrating the state of adjusting the height of the trailer with the first and second height adjustment units depicted in FIG. 12.

FIG. 16 is a side view illustrating the first moving unit, the second moving unit, the third moving unit, the spraying unit, and the sensing unit depicted in FIG. 12.

### BEST MODE OF THE INVENTION

Below, a detailed description of the present invention is provided with reference to the accompanying illustrating. This invention may be subject to various modifications and may take on several forms. Therefore, specific embodiments are illustrated in the drawings and described in detail in the specification. However, this is not intended to limit the invention to any particular embodiment, and it should be understood to encompass all variations, equivalents, and alternatives falling within the scope of the invention's concepts and principles. In explaining each drawing, similar reference symbols have been used for similar components. In the attached drawings, the dimensions of the structures are magnified for clarity of the present invention

The terms “first,” “second,” etc., may be used to describe various components, but the components should not be limited by these terms. The above terms are used solely for distinguishing one component from another. For example, within the scope of the present invention, the first component may be referred to as the second component without departing from the scope of the invention, and similarly, the second component may also be referred to as the first component.

The terminology used in this application is solely for the purpose of describing specific embodiments and is not intended to limit the scope of the invention. The singular expressions include the plural expressions unless context explicitly indicates otherwise. In this application, terms such as “include” or “have” are intended to specify that the features, numbers, steps, operations, components, sub-parts, or combinations thereof, as listed in the specification, are present, rather than to exclude the existence or possibility of one or more other features, numbers, steps, operations, components, sub-parts, or combinations thereof.

Unless otherwise defined, all terms used herein, including technical or scientific terms, have the same meaning as commonly understood by a person with ordinary skill in the art to which this invention pertains. Terms that are defined in a commonly used dictionary should be interpreted as having the meaning consistent with the context of the relevant technology, and unless explicitly defined in this application, they are not interpreted in an idealized or overly formal sense.

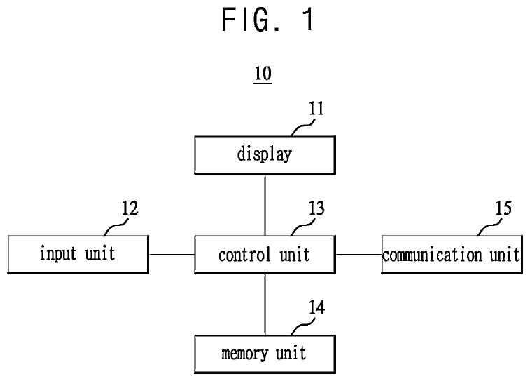

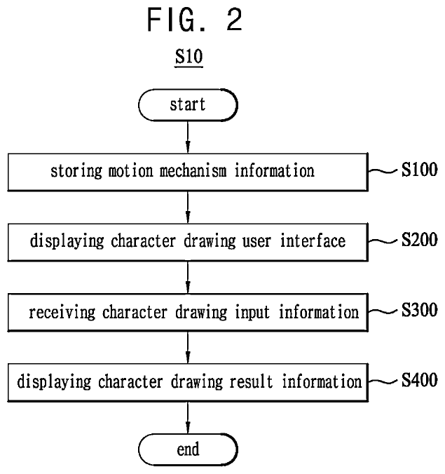

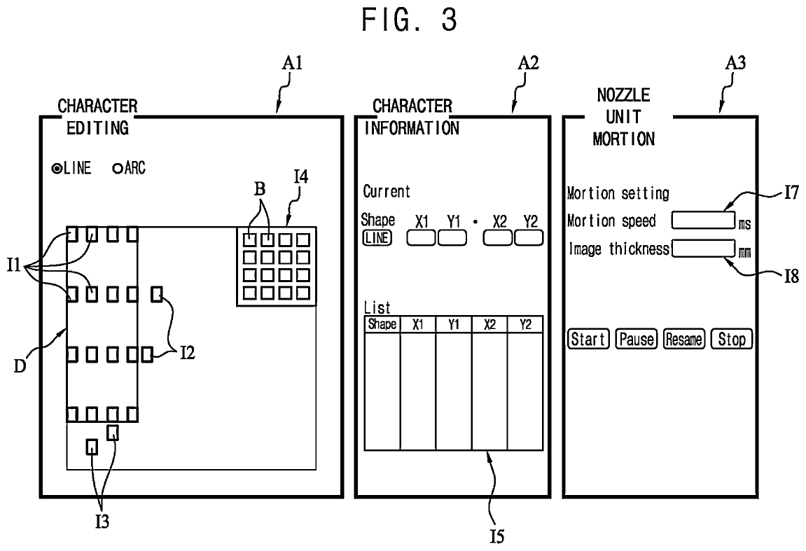

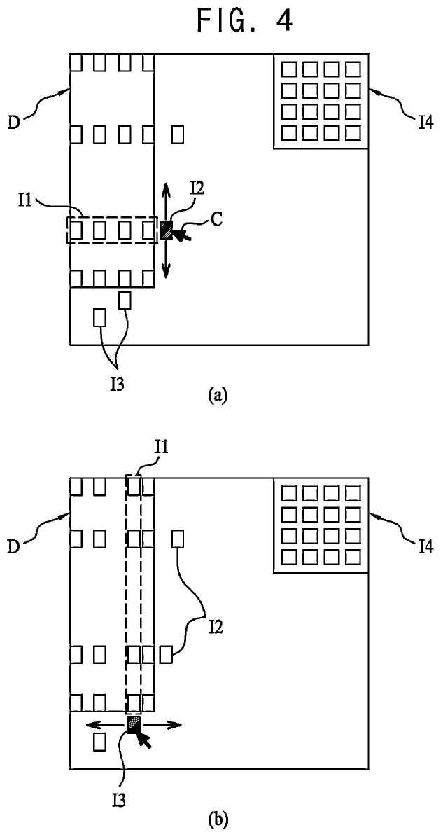

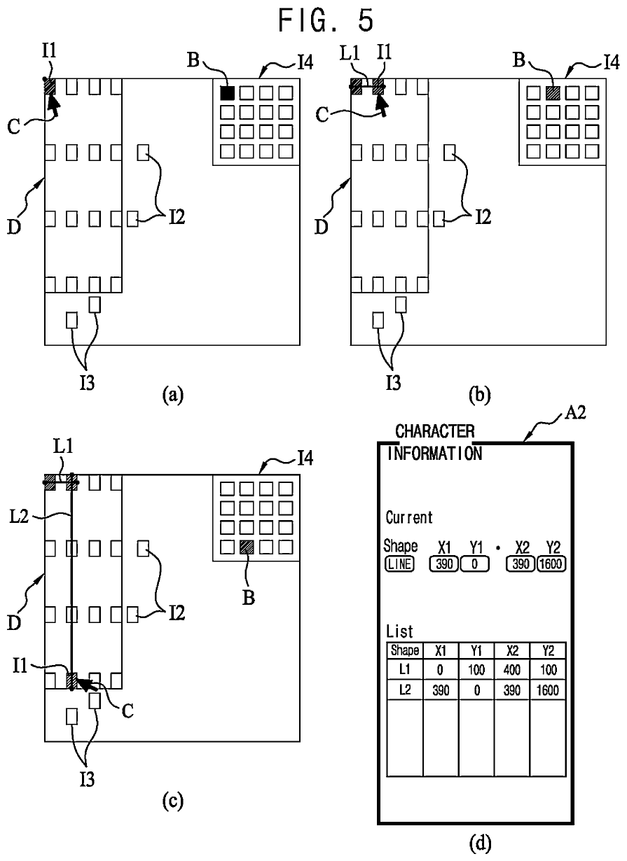

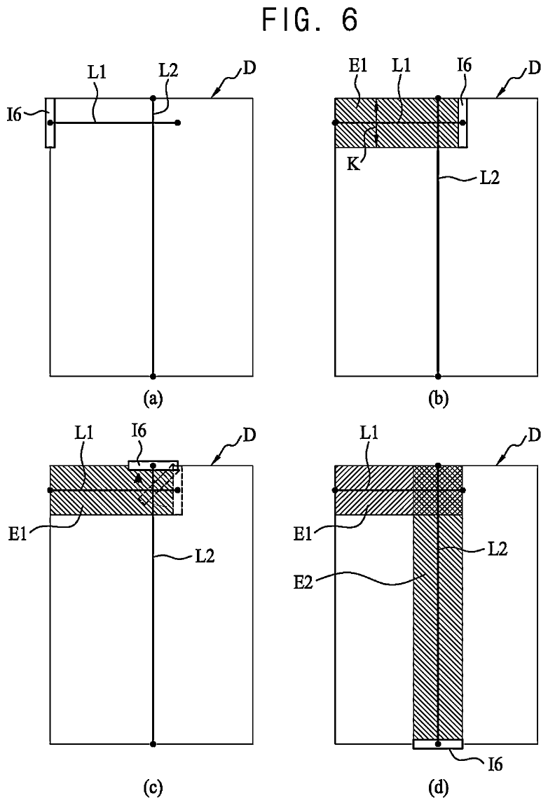

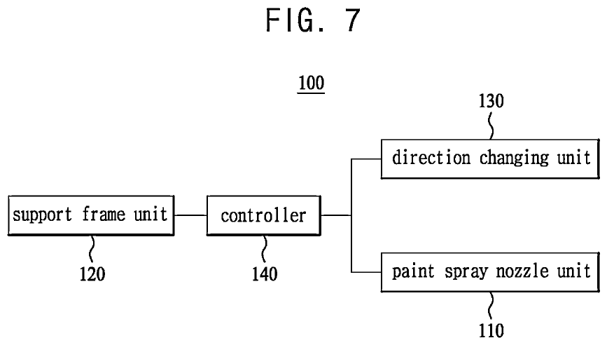

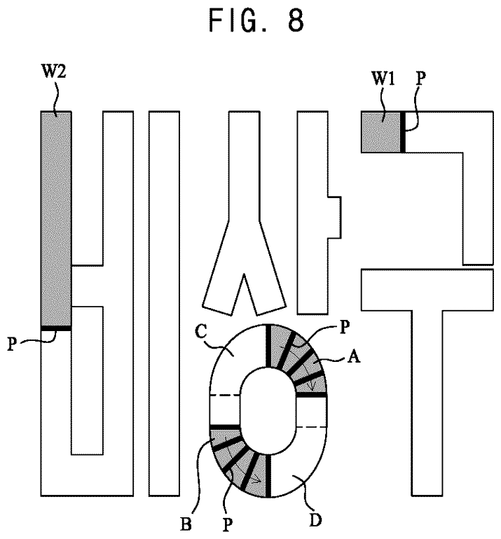

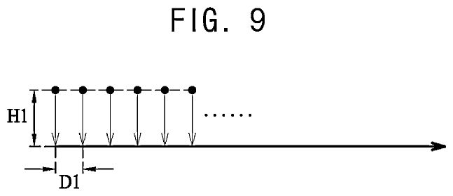

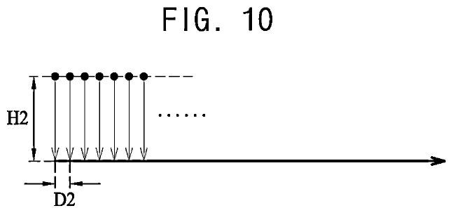

FIG. 1 is a schematic block diagram of a character drawing system implementing a character drawing method according to an embodiment of the present invention. FIG. 2 is a schematic flowchart diagram of a character drawing method according to an embodiment of the present invention. FIG. 3 is a schematic illustration of a character plotting user interface provided by a character drawing method according to an embodiment of the present invention. FIG. 4 is a schematic diagram for explaining the vertical direction movement icons and horizontal direction movement icons provided by a character drawing method according to an embodiment of the present invention. FIG. 5 is a schematic diagram for explaining the character editing interface provided by a character drawing method according to an embodiment of the present invention. FIG. 6 is a schematic diagram for explaining the motion icons provided by a character drawing method according to an embodiment of the present invention. FIG. 7 is a block diagram for explaining an automatic image coloring device according to the present invention. FIG. 8 is a diagram illustrating the process of a specific image being colored on a target surface by an automatic image painting device according to the present invention FIGS. 9 and 10 are diagrams illustrating the distance from the target surface and the unit distance traveled per unit time (speed) for the coating spray nozzle unit used to paint a specific area.

The character drawing method according to an embodiment of the present invention lies in providing a method whereby an operator may easily draw characters to be painted by an automatic image painting device.

First, before explaining the character drawing method according to an embodiment of the present invention, reference will be made to the aforementioned automatic image painting device, as described in FIG. 7 or 10.

Referring to FIG. 7, the automatic image painting device 100 according to the present invention may be a device for painting a specific image with paint onto a target surface such as a wall surface of a building or a specific floor surface.

Here, the specific image may include drawings, characters, symbols, logos, etc. In the following, the example of “ [symbol] ” (Emergency Exit) in Korean characters will be used to explain how to indicate the evacuation direction for people in case of an emergency on a target surface of a specific floor.

The automatic image painting device 100 may include a paint spraying nozzle unit 110 for spraying paint, a support frame unit 120 for supporting the paint spraying nozzle unit 110, a direction changing unit 130 for rotating the paint spraying nozzle unit 110, and a controller 140 for controlling the overall operation.

The paint spraying nozzle unit 110 is a component for spraying paint in a straight-line pattern (P, FIG. 8) with a predetermined length on the target surface. The front-end cross-section of the paint spraying nozzle unit 110 may be formed in a rectangular shape, but the front-end cross-section is not necessarily limited to this shape.

The support frame unit 120 has no restrictions on its shape as long as the support frame unit 120 may support the paint spraying nozzle unit 110 to move along the X-axis, Y-axis, and Z-axis. Additionally, the support frame unit 120 may automatically move to the target surface by means of wheels.

Naturally, the support frame unit 120 may also be capable of moving its position on the target surface.

The movement of the paint spraying nozzle unit 110 on the support frame unit 120 may be implemented using various well-known methods such as a ball screw mechanism with a drive motor, chain mechanism, belt mechanism, cylinder mechanism, and/or gear mechanism. Detailed descriptions of these methods are omitted.

The direction changing unit 130 is a component that may rotate the paint spraying nozzle unit 110 at a predetermined position on the support frame unit 120 to change the orientation of the straight-line pattern. The direction changing unit 130 may include a step motor.

The operation of the direction changing unit 130 may be performed independently of the movement of the paint spraying nozzle unit 110 along the X-axis, Y-axis, and Z-axis on the support frame unit 120. As a result, multiple operations may be performed simultaneously.

The controller 140 is a type of control device for controlling the position movement of the paint spraying nozzle unit 110 on the support frame unit 120 and the rotational movement of the paint spraying nozzle unit 110. The controller 140 may control the overall operation of the automatic image painting device 100 according to the present invention, including the position movement of the support frame unit 120.

Meanwhile, the controller 140 may control the position movement of the paint spraying nozzle unit 110 along the Z-axis on the support frame unit 120 to adjust the distance between the paint spraying nozzle unit 110 and the target surface, thereby regulating the width of the specific image being painted on the target surface.

Additionally, the controller 140 may control the movement speed of the paint spraying nozzle unit 110 along the X-axis and the Y-axis on the support frame unit 120 to adjust the coating thickness of the specific image being painted on the target surface.

The specific operation control of the paint spraying nozzle unit 110 by the controller 140 is described in detail, using a specific image shown in FIG. 8 as an example.

FIG. 8 is a diagram generated by the automatic image painting device according to the present invention, illustrating the process of a specific image being painted on the target surface.

Furthermore, FIGS. 9 and 10 are diagrams explaining the distance from the target surface and the distance traveled (speed) per unit time by the paint spraying nozzle for painting specific images.

Referring to FIG. 8, the specific image painted by the automatic painting device 100 according to the present invention may be the korean character “ [symbol] ” that may indicate the evacuation direction for people in case of emergency on the target surface on a specific floor.

When the specific image, as described above, is painted on the target surface on the floor surface, the specific image should be legible from the perspective of people rushing in an emergency, and therefore, the specific image should employ perspective to fulfill its essential function of conveying information.

For this reason, the specific image should be painted as shown in FIG. 8, with the horizontal lines W1 relatively wider than the vertical lines W2 from the perspective of people rushing in emergency, and overall, the specific image should be formed long in the vertical direction overall.

Furthermore, despite the difference in width, the thickness of the coating layer should be maintained consistently.

According to the present invention, in the automatic image painting device 100, when painting the second line portion (vertical line portion, W2) of the specific image, where the first line portion (horizontal line portion, W1) is wider than the second line portion (vertical line portion, W2), the state of the paint spray nozzle unit 110 is adjusted based on the position along the Z-axis. Specifically, the paint spray nozzle unit 110 is moved along the Z-axis to increase the distance between the paint spray nozzle unit 110 and the target surface. Additionally, the movement speed of the paint spray nozzle unit 110 on the support frame unit 120 is decreased to adjust the state of the paint spray nozzle unit 110.

FIG. 9 explains the operation of the paint spray nozzle unit 110 during the painting process of the vertical line portionW2 of the specific image shown in FIG. 8. FIG. 10 explains the operation of the paint spray nozzle unit 110 during the painting process of the horizontal line portionW1 of the specific image shown in FIG. 8.

In FIG. 9, the distance H1 between the paint spray nozzle unit 110 and the target surface is relatively closer compared to the distance H2 shown in FIG. 10, allowing for the painting of a relatively narrower stroke.

Additionally, in FIG. 9, the movement distance D1 per unit time of the paint spray nozzle unit 110 is greater than the movement distance D2 shown in FIG. 10. In other words, the speed increases, ensuring that the coating thickness remains consistent despite the difference in width.

Meanwhile, the specific image shown in FIG. 8 may also include curved line portions A, B, C in addition to the horizontal line portionW1 and the vertical line portion W2.

The curved line portions are mainly used for the character “0” and may include rightward downward curved line portions A, B and leftward downward curved line portions C, D.

Here, the rightward downward curved line portions A, B may include approximately “ [symbol] ” shaped curved line portions A and approximately “ [symbol] ” shaped curved line portions B. The leftward downward curved line portions C, D may include approximately inverted “ [symbol] ” shaped curved line portions C and approximately inverted “ [symbol] ” shaped curved line portions D.

Approximately “ [symbol] ” shaped curved line portion A and approximately inverted “ [symbol] ” shaped curved line portion C are connected to the wider horizontal line portionW1 at the upper portion and to the narrower vertical line portionW2 at the lower portion.

Additionally, the approximately “L” shaped curved line portion B and the approximately inverted “L” shaped curved line portion D are connected to the narrower vertical line portionW2 at the upper portion and to the wider horizontal line portionW1 at the lower portion.

Naturally, in the case of the character “0,” the horizontal line portionW1 or the vertical line portionW2 may not be present.

To enable the right downward curved line portions A, B or left downward curved line portions C, D to be painted by the paint spray nozzle unit 110, the controller 140 adjusts the movement of the paint spray nozzle unit 110 on the support frame unit 120 along the X and Y axes at variable speeds. Additionally, the controller 140 controls the direction changing unit 130 to gradually increase the rotation angle of the paint spray nozzle unit 110. Furthermore, the controller 140 may move the paint spray nozzle unit 110 along the Z-axis to vary the distance between the paint spray nozzle unit 110 and the target surface.

For example, if the approximately “ [symbol] ” shaped curved line portion A is to be painted starting from the upper portion by the paint spray nozzle unit 110, the controller 140 controls the direction changing unit 130 to rotate the paint spray nozzle unit 110. Additionally, the controller 140 also moves the paint spray nozzle unit 110 along the Z-axis to decrease the distance between the paint spray nozzle unit 110 and the target surface. Furthermore, the controller 140 may change the state of the paint spray nozzle unit 110 to increase the movement speed.

In other words, the controller 140 controls the direction change unit 130 so that the rotation angle of the paint spray nozzle unit 110 gradually increases. This ensures that the direction of the straight-line pattern, having a predetermined length, changes along the approximately “ [symbol] ” shaped rightward downward curved line portionA. The controller 140 moves the paint spray nozzle unit 110 along the Z-axis to gradually decrease the distance between the paint spray nozzle unit 110 and the target surface. Additionally, the controller 140 changes the state of the paint spray nozzle unit 110 to gradually increase the movement speed.

In another example, if the approximately “L” shaped curved line portionB is to be painted starting from the upper portion by the paint spray nozzle unit 110, the controller 140 controls the direction change unit 130 to rotate the paint spray nozzle unit 110. Additionally, the controller 140 also moves the paint spray nozzle unit 110 along the Z-axis to increase the distance between the paint spray nozzle unit 110 and the target surface. Furthermore, the controller may change the state of the paint spray nozzle unit 110 to decrease the movement speed.

In other words, the controller 140 controls the direction change unit 130 so that the rotation angle of the paint spray nozzle unit 110 gradually increases, causing the direction of the straight-line pattern, having a predetermined length, to change along the approximately “ [symbol] ” shaped curved line portionB. The controller moves the paint spray nozzle unit 110 along the Z-axis to gradually increase the distance between the paint spray nozzle unit 110 and the target surface. Additionally, the controller changes the state of the paint spray nozzle unit 110 to gradually decrease the movement speed.

Meanwhile, the controller 140 may control the paint spray nozzle unit 110 and the direction change unit 130 to vary the curvature radius of the outer line of the rightward downward curved line portions A, B or the leftward downward curved line portions C, D painted by the paint spray nozzle unit 110.

Additionally, the controller 140 may control the paint spray nozzle unit 110 and the direction change unit 130 to maintain a constant curvature radius of the inner line of the rightward downward curved line portions A, B or the leftward downward curved line portions C, D painted by the paint spray nozzle unit 110.

As described above, the controller 140 may control the movement direction along the Z-axis and the movement speeds along the X and Y axes of the paint spray nozzle unit 110 differently depending on the painting direction of the curved line portions A, B, C, D. This allows for the painting of curved line portions A, B, C, D with improved readability by applying perspective.

Below, the method for drawing characters S10 that provides an environment in which a user may easily draw characters to be painted by the automatic painting device 100 will be described.

For example, the character drawing method S10 may be implemented in a character drawing system 10.

For instance, FIG. 1 is a schematic block diagram of the character drawing system 10.

For example, the character drawing system 10 may include a display 11 that provides a character drawing user interface A for the user to draw characters, an input unit 12 for receiving predetermined input values from the user, a memory unit 14 for pre-storing data/information/computation values necessary for implementing the character drawing method S10, a control unit 13 for calculating and processing data/information/computation values necessary for implementing the character drawing method S10, and a communication unit 15 for communicating with the automatic painting device 100 or external devices.

Below, with reference to FIGS. 2 to 6, the character drawing method S10 implemented in the character drawing system 10 will be described in detail.

For example, the character drawing method S10 may include a step S100 in which the memory unit 14 stores motion mechanism information of the paint spray nozzle unit 110 of the automatic painting device 100.

For example, the step S100 of storing the motion mechanism information may include not only the motion mechanism information described below but also pre-storing the data/information/computation values necessary for implementing the character drawing method S10.

For instance, if the control method for controlling the motion (movement) of the paint spray nozzle unit 110 by the controller 140 of the automatic painting device 100 is updated, the memory unit 14 may store the updated control method information from the automatic painting device 100 via the communication unit 15.

Meanwhile, the character drawing method S10 may include a step S200 in which the display 11 shows the character drawing user interface A to the user.

To explain this in detail, FIG. 3 is an example of the character drawing user interface A. The user may access the character drawing user interface A through the display 11.

For example, the character drawing user interface A may broadly include a character editing interface A1, a character information interface A2, and a motion interface A3 for the paint spray nozzle unit 110.

For example, the character editing interface A1, the character information interface A2, and the motion interface A3 may all be displayed simultaneously on a single screen divided by the display 11.

For instance, the character editing interface A1 may include icons (LINE, ARC) that allow the user to select whether the stroke of the character to be drawn will be a straight line or an arc (curve). Furthermore, the character editing interface A1 may include a character input interface D that enables the creation and editing of characters, which will be explained in detail below.

Here, for example, the character input interface D may display multiple input icons 11 arranged horizontally and vertically, allowing the user to input the strokes of the character.

Additionally, although not shown in the figures, the character input interface D may display a ruler and grid lines in the background of the multiple input icons I1 arranged horizontally and vertically.

For instance, the input icons I1 may be formed as a 4×4 grid of multiple icons arranged horizontally and vertically.

Additionally, adjacent to the input icons I1, the character input interface D may also display vertical move icons 12 for moving multiple input icons I1 vertically and horizontal move icons I3 for moving multiple input icons I1 horizontally.

Furthermore, the character editing interface A1 may display block icons I4, which group multiple input icons I1 into several blocks B.

For example, the block icons 14 may be arranged as a 4×4 grid of blocks B, corresponding to the position and number of the input icons I1.

Meanwhile, the character information interface A2 may display information about the strokes of the characters input by the user through the input icons I1.

For example, the character information interface A2 may include an interface that displays information about the current strokes input by the user, and an interface that displays a list of information about the accumulated strokes of the characters.

Meanwhile, the motion interface A3 may include a speed control icon I7 and a thickness control icon 18 for setting the position movement of the motion icon I6, which will be described below.

Meanwhile, the character drawing method S10 may further include a step S300 in which the input unit 12 receives character drawing input information from the user and a step S400 in which the display 11 shows the character drawing result information corresponding to the character drawing input information to the user.

For example, the step S300 of receiving the character drawing input information may mean obtaining information input by the user through the input unit 12 such as a keyboard or mouse on the character drawing user interface A.

For example, the step S400 of displaying the character drawing result information may mean displaying the character drawing result information, which is derived by the control unit 13 through computation/processing of the information input by the user in the step S300 of receiving the character drawing input information, on the character drawing user interface A.

Therefore, the user may see the result of their character drawing input values on the display 11 through the step S400 of displaying the character drawing result information.

Below, with reference to FIGS. 4 and 6, the character drawing method S10 will be described in more detail.

FIG. 4 is a diagram explaining the position movement of the input icons I1 through the vertical move icons 12 and the horizontal move icons I3.

For example, as shown in FIG. 4(a), in the step S300 of receiving the character drawing input information, the user may click the vertical move icon 12 on the character input interface D through the input unit 12 and, while holding the click, scroll vertically to input character drawing input information that moves the vertical move icon 12 in the vertical direction.

In this case, the step S400 of displaying the character drawing result information may display the character drawing result information where the four input icons I1, which are pre-matched (indicated by dotted lines) in the horizontal direction with the vertical move icon I2, are moved vertically to the same position as the vertical move icon I2.

Therefore, the user may very easily move multiple input icons I1 vertically by moving the position of the vertical move icon I2

Meanwhile, as shown in FIG. 4(b), in the step S300 of receiving the character drawing input information, the user may click the horizontal move icon 13 on the character input interface D through the input unit 12 and, while holding the click, scroll horizontally to input character drawing input information that moves the horizontal move icon 13 in the horizontal direction.

In this case, the step S400 of displaying the character drawing result information may display the character drawing result information where the four input icons I1, which are pre-matched (indicated by dotted lines) in the vertical direction with the horizontal move icon I3, are moved horizontally to the same position as the horizontal move icon I3.

Therefore, the user may very easily move multiple input icons I1 horizontally by moving the position of the horizontal move icon I3.

The horizontal move icons I3 and the vertical move icons 12 may each be displayed in multiple quantities for the horizontal and vertical directions of the multiple input icons (I), respectively.

FIG. 5 is a diagram explaining how a user inputs the strokes of the character “ [symbol] ” through the input icons I1 after moving the positions of multiple input icons I1 using the horizontal move icons 13 and vertical move icons I2.

For example, as shown in FIG. 5(a), in the step S300 of receiving the character drawing input information, the user may place the cursor C of the mouse over the 1-row×1-column input icon I1 among the multiple input icons I1 (i.e., select it)

In this case, the step S400 of displaying the character drawing result information may display the 1-row×1-column block B, corresponding to the 1-row×1-column input icon I1, on the block icon 14 with a different color or shape to distinguish the block B from the other blocks B.

As a result, the user may easily recognize the selected input icon I1 through the block icon I4.

Afterward, the user may click to select the 1-row×1-column input icon I1.

Then, as shown in FIG. 5(a), in the step S300 of receiving the character drawing input information, the user may place the cursor C of the mouse over the 1-row x 2-column input icon I1 among the multiple input icons I1 (i.e., select it).

In this case, the step S400 of displaying the character drawing result information may display the 1-row×2-column block B, corresponding to the 1-row×2-column input icon I1, on the block icon 14 with a different color or shape to distinguish the block B from the other blocks B.

Afterward, the user may click to select the 1-row×2-column input icon I1.

In this case, the step S400 of displaying the character drawing result information may display the first stroke L1 of the character, connecting the 1-row×1-column input icon I1 and the 1-row×2-column input icon I1.

Then, as shown in FIG. 5(c), in the step S300 of receiving the character drawing input information, the user may place the cursor C of the mouse over the 4-row×2-column input icon I1 among the multiple input icons I1 (i.e., select it).

In this case, the step S400 of displaying the character drawing result information may display the 4-row×2-column block B, corresponding to the 4-row×2-column input icon I1, on the block icon 14 with a different color or shape to distinguish the block B from the other blocks B.

Afterward, the user may click to select the 4-row×2-column input icon I1.

In this case, the step S400 of displaying the character drawing result information may display the second stroke L2 of the character, connecting the 1-row×2-column input icon I1 and the 4-row×2-column input icon I1.

Therefore, the user may see the “ [symbol] ” character they have drawn on the character input interface D.

Meanwhile, FIG. 5(d) shows the information displayed on the character information interface A2 in the state of FIG. 5(c).

As shown in FIG. 5(d), in the step S400 of displaying the character drawing result information, the character information interface A2 may display distance icons 15 that include the distance information in the horizontal and vertical directions from a predetermined reference point Z to indicate the positions of one end and the other end of the stroke of the character input by the user.

To explain this in more detail, the reference point Z may be the top-left point on the character input interface D. When the user inputs the first stroke L1, the character information interface A2 may display the distance from the reference point Z to one end of the first stroke L1 as X (horizontal direction, X1) and Y (vertical direction, Y1), and the distance to the other end of the first stroke L1 as X (horizontal direction, X2) and Y (vertical direction, Y2).

Additionally, when the user inputs the second stroke L2, the character information interface A2 may display the distance from the reference point Z to one end of the second stroke L2 as X (horizontal direction, X1) and Y (vertical direction, Y1), and the distance to the other end of the second stroke L2 as X (horizontal direction, X2) and Y (vertical direction, Y2).

The distance described may be indicated by the distance icon I5.

When the user clicks on a specific distance icon 15, the corresponding stroke on the character input interface D may be selected and changed to a different color to distinguish the corresponding stroke from other strokes.

Meanwhile, the character drawing method S10 may further include a step S100 of storing the motion mechanism information.

As described earlier, the motion mechanism information may refer to the information that controls the position movement of the paint spray nozzle unit 110 of the automatic painting device 100 by the controller 140.

Here, for example, as previously described, the step S200 of displaying the character drawing user interface A may display the motion interface A3, which may simulate the motion of the paint spray nozzle unit 110.

Below, with reference to FIG. 6, the method for simulating the motion of the paint spray nozzle unit 110 will be described in more detail.

For example, in the step S400 of displaying the character drawing result information, a motion icon I6 representing the motion of the paint spray nozzle unit 110 may be displayed on the character input by the user.

For instance, the motion icon I6 may be an image representing the paint spray nozzle unit 110 and may be displayed on the character input interface D.

FIG. 6(a) shows the first stroke L1 and the second stroke L2 of the “ [symbol] ” character input by the user through the input icon I1 displayed on the character input interface D, and the motion icon I6 may be displayed on the character input interface D.

Here, when the user clicks the ‘start’ icon (shown in FIG. 3) displayed on the motion interface A3, as shown in FIGS. 6(a) and 6(b), the motion icon 16 may be displayed on the character input interface D depicting the actual motion where the paint spray nozzle unit 110 moves along the first stroke L1 and the painting image (first painting image, E1) that the paint spray nozzle unit 110 paints on the first stroke L1.

As a result, with respect to the first stroke L1 drawn by the user, the user may recognize in advance what image how the paint spray nozzle unit 110 of the automatic painting device 100 will move and what image the paint spray nozzle unit 110 will be painted in the future.

Additionally, FIGS. 6(c) and 6(d) show the motion of the motion icon 16 for the second stroke L2. As shown in FIG. 6(c), the motion icon I6 may display the movement from the end point of the first stroke L1 (the point where painting was completed on the first stroke L1) to the starting point of the second stroke L2 (the point where painting will begin on the second stroke L2).

Additionally, as shown in FIG. 6(d), the motion icon I6 may be displayed on the character input interface D, depicting the actual motion of the paint spray nozzle unit 110 along the second stroke L2 and the painting image (second painting image, E2) being painted by the paint spray nozzle unit 110 on the second stroke L2.

As a result, with respect to the first stroke L2 drawn by the user, the user may recognize in advance what image how the paint spray nozzle unit 110 of the automatic painting device 100 will move and what image the paint spray nozzle unit 110 will be painted in the future.

Meanwhile, as shown in FIG. 3, the motion interface A3 may include a speed control icon I7 for adjusting the movement speed of the motion icon I6 and a thickness control icon I8 for adjusting the thickness K of the painting image.

The user may input the movement speed of the motion icon 16 into the input window of the speed control icon I7, and the motion icon 16 that moves on the character input interface D will move along the first stroke L1 and the second stroke L2 at the speed corresponding to the speed input by the user.

Additionally, the user may input the thickness of the painting image created by the motion icon I6 in the input window of the thickness control icon 18. The thickness K of the painting image displayed as the motion icon I6 moves on the character input interface D will correspond to the thickness input by the user and will be displayed on the first stroke L1 and the second stroke L2.

The step S400 of displaying the character drawing result information, as previously described, may be implemented under the control of the control unit 13.

In other words, the control unit 13 may process the user's input values obtained through the step S300 of receiving the character drawing input information so that the character drawing result information described above is displayed on the character drawing user interface A.

Meanwhile, a recording medium according to another embodiment of the present invention may refer to a computer-readable recording medium on which a program for executing the character drawing method S10 is recorded.

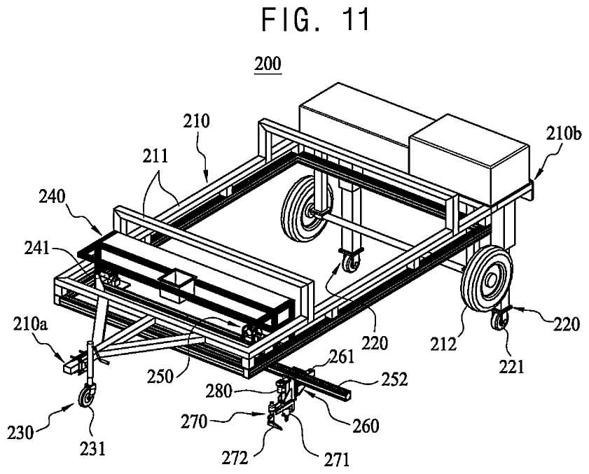

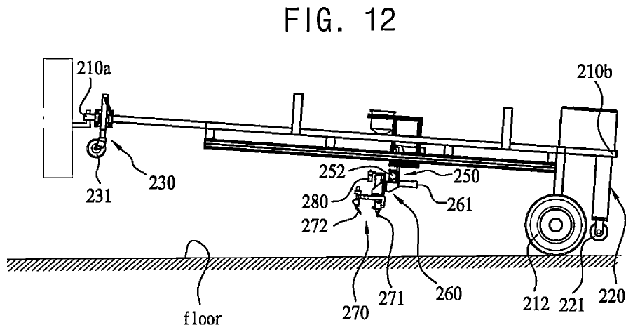

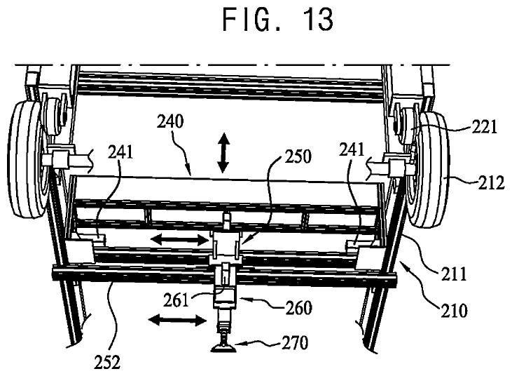

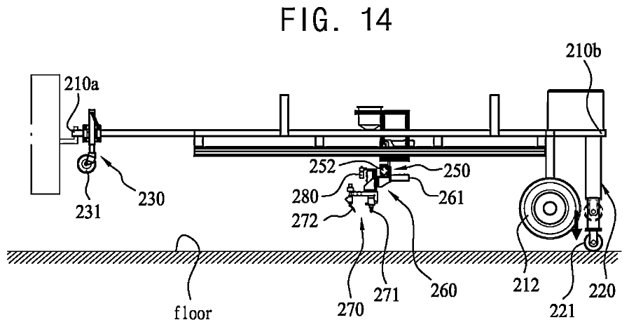

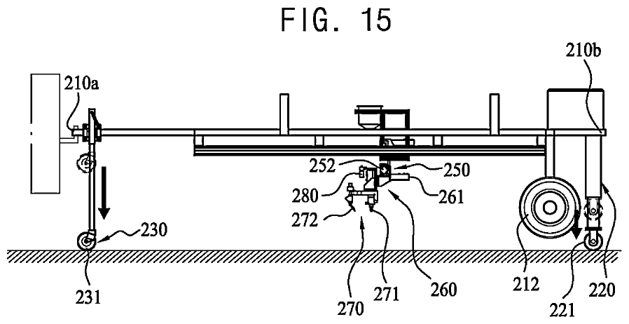

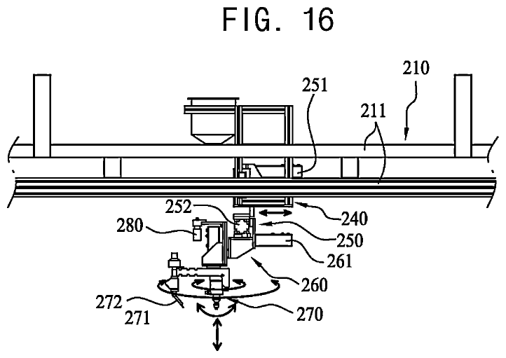

FIG. 11 is a perspective view of an automatic image painting device according to another embodiment of the present invention, and FIG. 12 is a side view of the automatic image painting device shown in FIG. 11 being towed by a towing vehicle. FIG. 13 is a perspective view of the automatic image painting device shown in FIG. 12. FIG. 14 is a side view of the state of adjusting the height of the trailer with the first height adjustment unit shown in FIG. 12, and FIG. 15 is a side view of adjusting the height of the trailer with the first height adjustment unit and the second height adjustment unit shown in FIG. 12. FIG. 16 is a side view of the first moving unit, second moving unit, third moving unit, spray unit, and detection unit shown in FIG. 12.

Referring to FIG. 11 or 16, the automatic image painting device 200 is for spraying paint onto the road surface and may include a trailer 210, a first height adjustment unit 220, a second height adjustment unit 230, a first moving unit 240, a second moving unit 250, a third moving unit 260, a spray unit 270, and a detection unit 280.

The trailer 210 is composed of multiple frames 211 connected horizontally and vertically.

A pair of running wheels 212 is provided at the rear end 210b of the trailer 210. The front end 210a of the trailer 210 protrudes forward and is connected to a towing vehicle. Therefore, the trailer 210 may be moved by being towed by the towing vehicle.

When the trailer 210 is connected to the towing vehicle, the trailer 210 may be inclined towards the rear lower side.

Alternatively, the trailer 210 may be in a horizontal state or inclined towards the rear upper side while connected to the towing vehicle.

Since the automatic image painting device 200 is towed and moved by the towing vehicle, the movement of the automatic image painting device 200 is convenient, and the position of the automatic image painting device 200 may be easily adjusted.

The first height adjustment unit 220 is provided at the rear end 210b of the trailer 210 to be elevatable, and the first height adjustment unit 220 adjusts the height of the rear end 210b of the trailer 210 (see FIG. 14).

Specifically, the first height adjustment unit 220 lowers to contact the road surface, and by continuing to lower while in contact with the road surface, the first height adjustment unit 220 may raise the rear end 210b of the trailer 210 to adjust the rear end 210b to the same height as the front end 210a.

For example, a reference height at which the front end 210a is connected to the towing vehicle is preset, and the first height adjustment unit 220 may adjust the rear end 210b to the same height as the reference height.

In another example, a first distance sensor and a second distance sensor (not illustrated) for measuring the distance to the road surface are provided at the front end 210a and the rear end 210b, respectively. After measuring the height of the front end 210a using the first distance sensor, the height of the rear end 210b is measured using the second distance sensor, and the first height adjustment unit 220 may adjust the height of the rear end 210b to be the same as the height of the front end 210a.

Examples of the first height adjustment unit 220 include an LM guide and linear motor, a ball screw and rotary motor, a pump and cylinder, etc.

The first height adjustment unit 220 may be controlled by a control unit (not illustrated). The control unit may control the second height adjustment unit 230, the first moving unit 240, the second moving unit 250, the third moving unit 260, the spray unit 270, and the detection unit 280.

Alternatively, the first height adjustment unit 220 may be operated manually by an operator.

To stably adjust the height of the rear end 210b of the trailer 210, a pair of first height adjustment units 220 may be provided.

A first moving wheel 221 is provided at the lower end of the first height adjustment unit 220. The first moving wheel 221 may be used for moving the trailer 210.

Additionally, although not shown in detail, the first height adjustment unit 220 may be provided with a fixing means to secure the first moving wheel 221.

Meanwhile, as the first height adjustment unit 220 raises the rear end 210b of the trailer 210, the running wheels 212 become separated from the road surface. Since the running wheels 212 are separated from the road surface, they do not affect the movement of the trailer 210.

After the first height adjustment unit 220 adjusts the height of the rear end 210b of the trailer 210, the automatic image painting device 200 may paint the road surface.

The second height adjustment unit 230 is provided at the front end 210a of the trailer 210 to be elevatable and adjusts the height of the front end 210a of the trailer 210 (see FIG. 15).

Specifically, when the front end 210a is separated from the towing vehicle, the second height adjustment unit 230 lowers to contact the road surface, and by continuing to lower while in contact with the road surface, the second height adjustment unit 230 may raise the front end 210a of the trailer 210 to adjust the front end 210a to the same height as the rear end 210b.

For example, a reference height at which the front end 210a is connected to the towing vehicle is preset, and the second height adjustment unit 230 may adjust the front end 210a to the same height as the reference height.

In another example, a first distance sensor and a second distance sensor (not illustrated) for measuring the distance to the road surface are provided at the front end 210a and the rear end 210b, respectively. After measuring the height of the rear end 210b using the second distance sensor, the height of the front end 210a is measured using the first distance sensor, and the second height adjustment unit 230 may adjust the height of the front end 210a to be the same as the height of the rear end 210b.

Examples of the second height adjustment unit 230 include an LM guide and linear motor, a ball screw and rotary motor, a pump and cylinder, etc.

The second height adjustment unit 230 may be controlled by the control unit or operated manually by an operator.

A second moving wheel 231 is provided at the lower end of the second height adjustment unit 230. The second moving wheel 231 may be used for moving the trailer 210.

Additionally, although not shown in detail, the second height adjustment unit 230 may be provided with a fixing means to secure the second moving wheel 231.

Therefore, when the trailer 210 is supported by the first height adjustment unit 220 and the second height adjustment unit 230, the trailer 210 may be moved using the first moving wheel 221 and the second moving wheel 231, and the trailer 210 may be stopped using the fixing means.

After the first height adjustment unit 220 adjusts the height of the rear end 210b of the trailer 210 and the second height adjustment unit 230 adjusts the height of the front end 210a of the trailer 210, the automatic image painting device 200 may paint the road surface.

The first moving unit 240, the second moving unit 250, and the third moving unit 260 may move the spray unit 270 and the detection unit 280 in the front-rear direction and left-right direction of the trailer 210.

The first moving unit 240 extends along the left-right direction of the frame of the trailer 210, with both ends coupled to the frame. Additionally, the first moving unit 240 may move in the front-rear direction along the frame. At this time, the first moving unit 240 may be moved by the first driving unit 241.

The second moving unit 250 is provided on the first moving unit 240 and may move in the left-right direction along the first moving unit 240. At this time, the second moving unit 250 may be moved by the second driving unit 251.

Additionally, the second moving unit 250 may include an extension member 252 that extends in the left-right direction. As the second moving unit 250 moves in the left-right direction, the extension member 252 also moves in the left-right direction. The extension member 252 may protrude outside the trailer 210 as the extension member 252 moves in the left-right direction. Therefore, the second moving unit 250 may protrude outside the trailer 210 in the left-right direction.

The third moving unit 260 is provided on the second moving unit 250 and may move in the left-right direction along the extension member 252 of the second moving unit 250. At this time, the third moving unit 260 may be moved by the third driving unit 261.

Although not illustrated in detail, the first driving unit 241, the second driving unit 251, and the third driving unit 261, which are driving means for moving the first moving unit 240, the second moving unit 250, and the third moving unit 260, respectively, may have LM guides and linear motors, ball screws and rotary motors, pumps and cylinders, rotary motors, pulleys and belts, rotary motors and gears, etc. applied.

The spray unit 270 is provided on the third moving unit 260 and may move in the front-rear direction and left-right direction of the trailer 210 by the first moving unit 240, the second moving unit 250, and the third moving unit 260.

The spray unit 270 may include a paint spray nozzle 271 that sprays paint towards the road surface. The paint spray nozzle 271 may spray the paint in a straight-line pattern.

Since the second moving unit 250 protrudes outside the trailer 210 in the left-right direction, the paint spray nozzle 271 may paint the road surface not only inside the trailer 210 but also outside the trailer 210 in the left-right direction. Therefore, the painting range of the paint spray nozzle 271 may be expanded.

Additionally, as the painting range of the paint spray nozzle 271 is expanded, the number of times the trailer 210 needs to be moved to paint the road surface may be relatively reduced, thereby reducing the time required for painting the road surface.

Meanwhile, the second moving unit 250 protrudes outside the trailer 210 only during the painting process using the paint spray nozzle 271. Therefore, when the trailer 210 is moving, the second moving unit 250 does not protrude outside the trailer 210, which prevents the second moving unit 250 from restricting or obstructing the movement of the trailer 210.

The paint spray nozzle 271 may be configured to rotate around a central axis in the vertical direction to adjust the direction of the straight-line pattern. For example, the paint spray nozzle 271 may be rotated by a step motor.

When the paint spray nozzle 271 is rotated so that the straight-line pattern of the paint spray nozzle 271 is perpendicular to the moving direction of the spray unit 270, the width of the paint sprayed from the paint spray nozzle 270 may be made uniform.

The paint spray nozzle 271 may be rotated so that the straight-line pattern of the paint spray nozzle 271 is not perpendicular to the movement direction of the spray unit 270 but forms a certain angle. By adjusting this angle, the width of the paint sprayed from the paint spray nozzle 270 may be varied.

The spray unit 270 may further include a bead spray nozzle 272 that sprays beads onto the paint applied to the road surface. These beads reflect the lights of vehicles moving at night.

The bead spray nozzle 272 is provided adjacent to the paint spray nozzle 271. The bead spray nozzle 272 may rotate around the paint spray nozzle 271 from the rear of the paint spray nozzle 271 in the direction of movement to spray beads. Therefore, after the paint is sprayed onto the road surface by the paint spray nozzle 271, the bead spray nozzle 272 may spray beads onto the applied paint.

The rotation of the paint spray nozzle 271 and the rotation of the bead spray nozzle 272 may be performed independently. Therefore, even if the paint spray nozzle 271 moves with its straight-line pattern forming a certain angle with the movement direction of the spray unit 270, the bead spray nozzle 272 may still be positioned at the rear of the paint spray nozzle 271 in the direction of movement.

The rotation of the paint spray nozzle 271 and the rotation of the bead spray nozzle 272 may consist of independent operations. Therefore, even if the paint spray nozzle 271 moves with its straight-line pattern forming a certain angle with the movement direction of the spray unit 270, the bead spray nozzle 272 may still be positioned at the rear of the paint spray nozzle 271 in the direction of movement.

If the straight-line pattern of the paint spray nozzle 271 is perpendicular to the movement direction of the spray unit 270 as the paint spray nozzle 271 moves, the paint spray nozzle 271 and the bead spray nozzle 272 may also rotate together.

The detection unit 280 is provided on the third moving unit 260 and may move in the left-right direction and the front-back direction along with the spray unit 270. The detection unit 280 detects the state of the road surface, including its slope, curvature, and the distance to the road surface, while moving in the left-right and front-back directions. Examples of the detection unit 280 include a camera or a scanner.

The paint spray nozzle 271 may be equipped to rotate around a horizontal axis parallel to the straight-line pattern to adjust the spray angle of the paint. For example, the paint spray nozzle 271 may adjust the spray angle of the paint using a step motor.

Additionally, the paint spray nozzle 271 may be configured to move vertically to adjust the distance from the road surface. For example, the paint spray nozzle 271 may move up and down using an LM guide and linear motor, ball screw and rotary motor, pump and cylinder, rotary motor, pulley and belt, rotary motor and gears, etc.

According to the inclination or curvature of the road surface detected by the sensor unit 280, the paint spray nozzle 271 adjusts its spray angle so that the paint spray angle of the nozzle 271 may be perpendicular to the road surface. Therefore, the paint may be sprayed in a direction perpendicular to the road surface.

By considering the vertical distance between the sensor unit 280 and the paint spray nozzle 271, the paint spray nozzle 271 may be moved up and down based on the distance to the road surface detected by the sensor unit 280, thus maintaining a consistent distance between the paint spray nozzle 271 and the road surface. Therefore, the paint may be sprayed at a uniform distance from the road surface.

Regardless of the condition of the road surface, by maintaining a constant distance between the paint spray nozzle 271 and the road surface, and ensuring that the paint spray angle of the nozzle 271 is perpendicular to the road surface, the paint may be applied with a consistent thickness. Therefore, the quality of painting using the automatic painting device 200 may be consistently maintained.

Although not illustrated in detail, the upper surface of the first moving unit 240 is equipped with a portion. This portion may equip a paint storage tank, heater, fuel tank, bead storage tank, compressor, input unit, display unit, and the control unit.

The paint storage tank stores paint and is connected to the paint spray nozzle 271 through piping. The paint storage tank may hold paint of various colors, such as yellow, blue, or white. The desired paint storage tank may be selected and replaced among the paint storage tanks depending on the color to be applied to the road surface.

The heater applies heat to the paint storage tank to keep the paint contained in the tank in a molten state.

The fuel tank stores the fuel used for heating in the heater and supplies the fuel to the heater.

The bead storage tank contains glass beads and is connected to the bead spray nozzle 272 through piping. Therefore, the glass beads stored in the bead storage tank are sprayed through the bead spray nozzle 272.

The compressor is connected to the paint spray nozzle 271 and the bead spray nozzle 272 through piping, and the compressor controls the pressure supplied to the paint spray nozzle 271 and the bead spray nozzle 272, thereby controlling the amount of paint and beads sprayed, respectively.

The input unit receives characters and symbols input by the user and may be composed of a keyboard, mouse, etc.

The display unit displays various signals input from the input unit to facilitate the operator's tasks.

The control unit converts the characters and symbols received from the input unit into drawings and generates driving signals based on the converted drawings.

### INDUSTRIAL APPLICABILITY

According to the automatic image painting device of the present invention, when painting a specific image of varying widths, the automatic image painting device may flexibly respond to changes in the painting process while maintaining a consistent coating thickness. This prevents deterioration of the painting quality in advance.

According to the character drawing method of the present invention, the operator may easily draw the characters to be painted by the automatic painting device.

The automatic image painting device according to the present invention is towed by a towing vehicle, so the movement of the device is convenient, and its position may be easily adjusted.

While the preferred embodiments of the present invention have been described above, those skilled in the art will understand that the present invention may be variously modified and altered without departing from the spirit and scope of the invention as defined in the following claims.

1. An automatic image painting device for painting a specific image on a target surface by spraying paint, comprising:
a paint spray nozzle unit for spraying paint on the target surface in a straight-line pattern of a predetermined length;
a support frame unit that supports the paint spray nozzle unit to enable movement along the X-axis, Y-axis, and Z-axis;
a direction changing unit that rotates the paint spray nozzle unit at a predetermined position on the support frame unit to change the orientation of the straight-line pattern; and
a control unit for controlling the movement of the paint spray nozzle unit on the support frame unit and the rotational movement of the paint spray nozzle unit,
wherein the control unit controls the Z-axis movement of the paint spray nozzle unit on the support frame unit to adjust the distance between the paint spray nozzle unit and the target surface, thereby regulating the width of the specific image painted on the target surface, and controls the movement speed of the paint spray nozzle unit along the X-axis and Y-axis on the support frame unit to adjust the coating thickness of the specific image painted on the target surface.

2. The automatic image painting device of claim 1, wherein the control unit moves the paint spray nozzle unit along the Z-axis to increase the distance between the paint spray nozzle unit and the target surface, and changes the state of the paint spray nozzle unit to decrease the movement speed when the first line portion included in the specific image is wider than the second line portion, based on the state of the paint spray nozzle unit for painting the second line portion.

3. The automatic image painting device of claim 1, wherein:
the specific image includes a right-downward curved line portion or a left-downward curved line portion; and
the control unit controls the paint spray nozzle unit to paint the right-downward curved line portion or the left-downward curved line portion by:
moving the paint spray nozzle unit along the surface axis and the nozzle axis at a variable speed on the support frame unit,
controlling the direction-changing unit to gradually increase the rotation angle of the paint spray nozzle unit, and
moving the paint spray nozzle unit along the Z-axis to vary the distance between the paint spray nozzle unit and the target surface.

4. The automatic image painting device of claim 3, wherein the control unit controls the paint spray nozzle unit and the direction-changing unit so that the curvature radius of the outer line of the right downward curved line portion or the left downward curved line portion painted by the paint spray nozzle unit, is variable.

5. The automatic image painting device of claim 4, wherein the control unit controls the paint spray nozzle unit and the direction-changing unit so that the curvature radius of the inner line of the right downward curved line portion or the left downward curved line portion, painted by the paint spray nozzle unit, is constant.

6. A method of drawing characters for drawing characters to be painted by an automatic painting device, comprising:
displaying a character drawing user interface to the user on the display;
receiving character drawing input information from the user via the input unit; and
displaying character drawing result information corresponding to the character drawing input information to the user on the display;
wherein the displaying the character drawing user interface includes:
displaying a plurality of input icons arranged in horizontal and vertical directions to allow the user to input strokes of the character, and
further displaying vertical direction movement icons to move the plurality of input icons in the vertical direction and horizontal direction movement icons to move the plurality of input icons in the horizontal direction.

7. The method of claim 6, wherein:
the displaying the character drawing user interface includes displaying block icons composed of a plurality of blocks, each block consisting of a plurality of input icons; and
the displaying the character drawing result information includes displaying the block corresponding to the selected input icons from the plurality of blocks of the block icons to be distinguished from the unselected blocks so that the selected input icons from the plurality of input icons is displayed.

8. The method of claim 6, wherein the displaying the character drawing result information includes displaying distance icons to indicate the positions of one end and the other end of the stroke of the characters input by the user, and the distance icons includes information on the horizontal and vertical distances from a predetermined reference point to one end and the other end of the stroke of the characters.

9. The method of claim 6, further comprising:
storing motion mechanism information of the paint spray nozzle unit of the automatic painting device in the memory unit;
wherein the displaying the character drawing user interface includes displaying a motion interface capable of simulating the motion of the paint spray nozzle unit.

10. The method of claim 9, wherein the displaying the character drawing result information includes displaying motion icons representing the motion of the paint spray nozzle on the character input by the user.

11. The method of claim 10, wherein the displaying the character drawing result information includes displaying a painting image painted by the paint spray nozzle unit on the character input by the user.

12. The method of claim 11, wherein the motion interface includes speed control icons that adjusts the moving speed of the motion icons.

13. The method of claim 11, wherein the motion interface includes thickness adjustment icons that adjusts the thickness of the painting image.
